(19) United States
(12) Patent Application Publication
(10) Pub. No.: US 2018/0114706 A1
(43) Pub. Date: Apr. 26, 2018

(54) WAFER BOAT ASSEMBLY AND SUBSTRATE PROCESSING APPARATUS INCLUDING THE SAME

(71) Applicant: SAMSUNG ELECTRONICS CO., LTD., Suwon-si (KR)

(72) Inventors: Sang Ryol YANG, Suwon-si (KR); Kyo Jun JEON, Seongnam-si (KR); Kun Tack LEE, Suwon-si (KR); Jong Heun LIM, Hwaseong-si (KR)

(21) Appl. No.: 15/495,088

(22) Filed: Apr. 24, 2017

(30) Foreign Application Priority Data
Oct. 25, 2016 (KR) 10-2016-0139532

(51) Int. Cl. H01L 21/673; H01L 21/67; C23C 16/455; C23C 16/458

(52) U.S. Cl. CPC H01L 21/6732; H01L 21/67017; C23C 16/4584; C23C 16/455; H01L 21/67098

(57) ABSTRACT

A wafer boat assembly including a boat, a pedestal, and a base. The boat includes a slot to hold a wafer and a rod including a gas line. The pedestal includes a first surface and a connection line coupled to the gas line. The base is on a second surface of the pedestal, rotates the pedestal, and supplies gas to the connection line. The boat is on the first surface of the pedestal. The gas flows along the gas line and is dispensed from a location where the rod contacts the wafer to levitate the wafer.

### CROSS-REFERENCE TO RELATED APPLICATION

Korean Patent Application No. 10-2016-0139532, filed on Oct. 25, 2016, and entitled, “Wafer Boat Assembly and Substrate Processing Apparatus Including the Same,” is incorporated by reference herein in its entirety.

### BACKGROUND

### 1. Field

One or more embodiments described herein relate to a wafer boat assembly and a substrate processing apparatus including a wafer boat assembly.

### 2. Description of the Related Art

A variety of processes may be used to manufacture a semiconductor device. Examples include photolithography, etching, diffusion, chemical vapor deposition, and ion implantation. These processes may be selectively and/or repeatedly performed on or more wafers. For example, chemical vapor deposition may be used to form thin films on wafers. During such a process, the wafers may be vertically stacked in a boat within reactor and then heated. Many problems may occur during processing. One problem may occur during a high temperature process is wafer deflection. This problem may defects (e.g., scratches, slips, etc.) at locations where the wafers physically contact the boat.

### SUMMARY

In accordance with one or more embodiments, a wafer boat assembly includes a boat including a slot to hold a wafer and a rod including a gas line; a pedestal including a first surface and a connection line coupled to the gas line; and a base, on a second surface of the pedestal, to rotate the pedestal and to supply a gas to the connection line, wherein the boat is on the first surface of the pedestal and wherein the gas is to flow along the gas line and is to be dispensed from a location at which the rod is in contact with the wafer in order to levitate the wafer.

In accordance with one or more other embodiments, a substrate processing apparatus includes a process tube; and a wafer boat assembly including: a boat including a slot to hold a wafer and a rod including a gas line; a pedestal including a first surface and a connection line coupled to the gas line; and a base, on a second surface of the pedestal, to rotate the pedestal and to supply a gas to the connection line, wherein the boat is on the first surface of the pedestal and wherein the gas is to flow along the gas line and is to be dispensed from a location at which the rod is in contact with the wafer in order to levitate the wafer.

In accordance with one or more other embodiments, a wafer boat assembly includes a boat including rod with an internal gas line; a pedestal with a connection line coupled to the gas line; and a base to rotate the pedestal and supply a gas to the connection line, wherein the gas is to be dispensed to levitate a wafer.

### BRIEF DESCRIPTION OF DRAWINGS

Features will become apparent to those of skill in the art by describing in detail exemplary embodiments with reference to the attached drawings in which:

FIG. 1 illustrates an embodiment of a substrate processing apparatus;

FIG. 2 illustrates an embodiment of a boat;

FIG. 3 illustrates an embodiment of portion A in the boat;

FIG. 4 illustrates a state where the boat is on and connected to a pedestal according to one embodiment;

FIG. 5 illustrates an embodiment of a base unit in a wafer boat assembly; and

FIG. 6 illustrates a state where a base unit is connected to the pedestal and the boat in a wafer boat assembly according to one embodiment.

### DETAILED DESCRIPTION

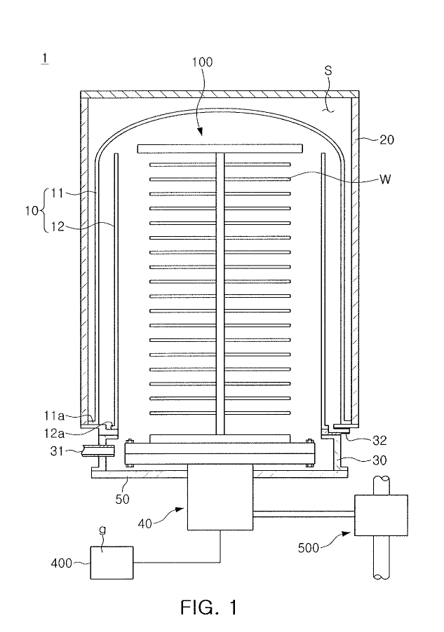

FIG. 1 illustrates a cross-sectional view of an embodiment of a substrate processing apparatus 1, which may have a vertical-type reactor structure and may include a process tube 10 and a sidewall insulating member 20.

The process tube 10 may be vertically extended in a height direction corresponding to a reaction chamber. The process tube 10 may include an internal tube 12 in a external tube 11. The internal tube 12 may have a predetermined (e.g., cylindrical) shape including an open upper portion and an open lower portion. The internal tube 12 may accommodate a boat 100, in which a plurality of wafers W are stacked in a vertical direction (e.g., a height direction).

The external tube 11 may have a predetermined (e.g., cylindrical) shape including a closed upper portion and an open lower portion and may seal the internal tube 12. The upper portion of the external tube 11 may have, for example, a convex structure similar to a dome shape. The external tube 11 and the internal tube 12 may be formed, for example, from a heat resistant material, e.g., quartz and silicon carbide.

The sidewall insulating member 20 may have a predetermined (e.g., substantially cylindrical) shape. The sidewall insulating member 20 may have an internal space S and may accommodate the process tube 10 therein. The sidewall insulating member 20 may be formed, for example, from a material having high insulating property, e.g., ceramic.

A heating line may be on an internal surface of the sidewall insulating member 20 to heat the process tube 10. The heating line may extend to have a spiral form on the internal surface of the sidewall insulating member 20, in a direction from a lower end portion thereof toward an upper end portion thereof. The heating line may be receive power from an external source in order to heat the internal space S to a predetermined temperature distribution.

A manifold 30 may be used to support the process tube 10. The manifold 30 may be below the external tube 11 and has a predetermined (e.g., substantially cylindrical) shape including an open upper portion and an open lower portion. The manifold 30 may be made from steel or another material.

An open lower end portion of the external tube 11 may have a flange 11a protruding in a radial direction. The flange 11a may on and support the manifold 30. A flange 12a of an open lower end portion of the internal tube 12 may be on the manifold 30 to be supported. The external tube 11 may be sealed by a sealing member (e.g., an O-ring) between the flange 11a and the manifold 30.

An introduction pipe 31 may be in the manifold 30 to dispense process gas into the process tube 10. The introduction pipe 31 may made, for example, from quartz, stainless steel, or an alloy.

The introduction pipe 31 may be connected to a gas supply pipe that includes a mass flow controller (MFC). The introduction pipe 31 may supply a predetermined amount of the process gas at a desired time through the MFC. The introduction pipe 31 may provide the process gas for a deposition process. A gas source may provide the process gas, for example, to deposit a predetermined film, e.g., a silicon oxide film or a silicon nitride film.

An exhaust pipe 32 may be on the manifold 30 to emit gas in the process tube 10 outwardly thereof. The exhaust pipe 32 may be connected to a space between the internal tube 12 and the external tube 11. The exhaust pipe 32 may be connected to an exhaust system (e.g., a vacuum pump) and may perform a vacuum exhaustion process to set the pressure in the process tube to a predetermined pressure level (e.g., a certain vacuum level).

A wafer boat assembly 40 may be below the manifold 30, so that the boat 100 on which a plurality of wafers W are mounted may be inserted into or extracted from the process tube 10. The wafer boat assembly 40 may include boat 100 on which a plurality of wafers W are mounted, a pedestal 200 on which the boat 100 is disposed, and a base unit 300 connected to the pedestal 200.

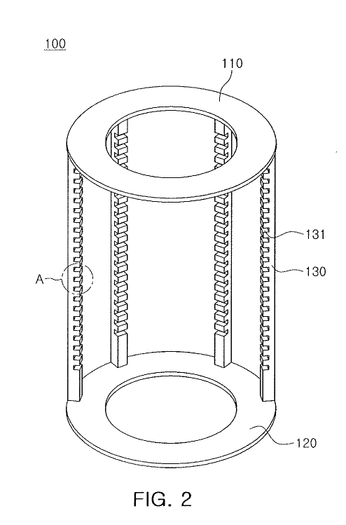

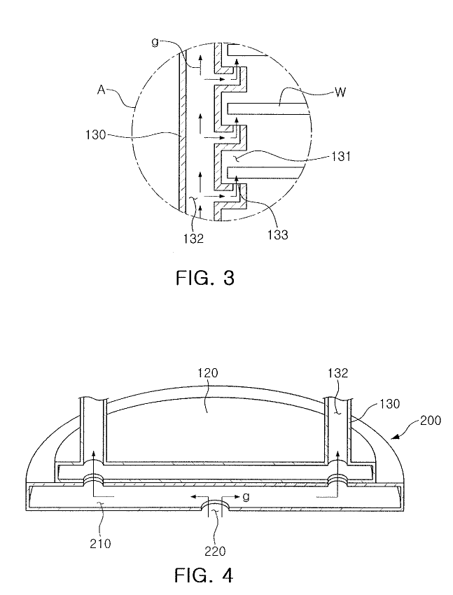

FIG. 2 illustrates an embodiment of the boat 100, and FIG. 3 illustrates a cross-sectional view of portion A in the boat 100.

Referring to FIGS. 2 and 3, the boat 100 may include at least one rod 130 connecting a top plate 110 and a bottom plate 120. The boat 100 may be made, for example, from a material resistant to thermal deformation in a high-temperature process and has high corrosion resistance, e.g., a ceramic material. In one embodiment, a plurality of rods 130 are provided and may include slots 131 arranged at a specific interval on an internal surface thereof. Wafers W may be held in the respective slots 131 in contact with the rods 130. The rod 130 may include a gas line 132 therein and a nozzle 133 connected to the gas line 132 at a location where the rod 130 is in contact with a wafer W in a slot 131. The boat 100 may be on one surface of a pedestal 200 and may be coupled thereto.

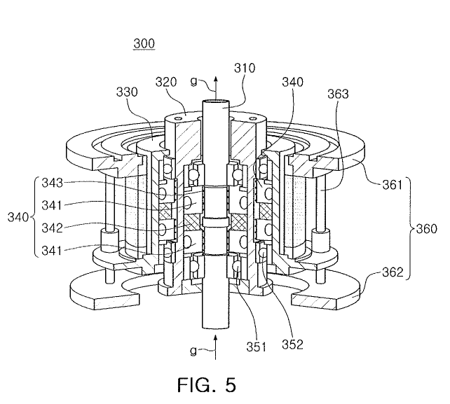

FIG. 4 illustrates a state in which the boat 100 is on and connected to a pedestal 200. The pedestal 200 has a predetermined (e.g., disk-type) structure with a diameter, for example, substantially greater than that of the bottom plate 120 of the boat 100. The pedestal 200 may include a connection line 210 connected to the gas line 132 on a first surface and an opening 220 connected to the connection line 210 on a second surface. The first surface may correspond to an upper surface of the pedestal 200. The second surface may face a base unit 300 (e.g., see FIG. 5) and may correspond to a lower surface of the pedestal 200. The base unit 300 may be on the second surface of the pedestal 200, rotate the pedestal 200, and supply gas to the connection line 210.

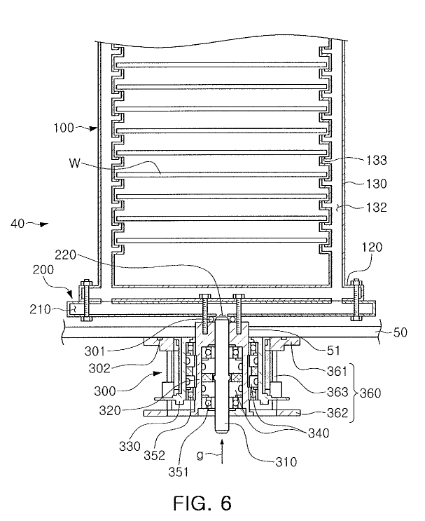

FIGS. 5 and 6 illustrate an embodiment of the base unit 300. FIG. 5 is a partially cutaway perspective view of the base unit 300 in a wafer boat assembly. FIG. 6 illustrates a cross-sectional view of a state where base unit 300 is connected to pedestal 200 and the boat 100 in the wafer boat assembly according to an example embodiment.

Referring to FIGS. 5 and 6, the base unit 300 may include a gas supply pipe 310, a rotary member 320, a housing 330, and a magnetic sealing portion 340. The base unit 300 may have a structure in which the rotary member 320 and the housing 330 are disposed to form a concentric circle centered on the gas supply pipe 310. The gas supply pipe 310 may be in a central region of the base unit 300 and may correspond to an axis of the base unit 300. The gas supply pipe 310 may have a pipe-type structure with open ends and an upper end portion facing the opening 220 of the pedestal 200.

A lower end portion of the gas supply pipe 310 may be connected to the gas storage chamber 400 to supply a gas g stored in the gas storage chamber 400 to the connection line 210 through the opening 220. The gas g may flow along the gas line 132 in the rod 130 and may be dispensed through the nozzle 133 of the slot 131, thereby levitating the wafer W. Therefore, the wafer W may not be in physical contact with the rod 130. The gas g may include, for example, nitrogen, hydrogen, helium, or argon.

The gas supply pipe 310 may be connected to an MFC and control flow rate, pressure, and/or the like, of the supply of gas g.

The rotary member 320 may have a predetermined (e.g., substantially cylindrical) structure and may be around the gas supply pipe 310. The rotary member 320 may be connected to a lower surface of the pedestal 200 and receive a rotational force from an external driving source 500 to rotate the pedestal 200. The rotary member 320 may be connected to the pedestal 200, for example, using a screw coupling method. An O-ring 301 may be on a contact surface between the rotary member 320 and the pedestal 200. The O-ring 301 may surround the opening 220 to prevent the gas g supplied through the gas supply pipe 310 from leaking.

The housing 330 may have a structure surrounding the rotary member 320 and may accommodate the gas supply pipe 310 and the rotary member 320 therein. The housing 330 may include, for example, a welded metal bellows.

The magnetic sealing portion 340 may be between the gas supply pipe 310 and the rotary member 320 surrounding the gas supply pipe 310. The magnetic sealing portion 340 may be between the rotary member 320 and the housing 330 surrounding the rotary member 320. The magnetic sealing portion 340 may seal a space between the gas supply pipe 310 and the rotary member 320 surrounding the gas supply pipe 310. The magnetic sealing portion 340 may also seal a space between the rotary member 320 and the housing 330 surrounding the rotary member 320, to thereby prevent gas in a process tube 100 from leaking out.

The magnetic sealing portion 340 may include a magnetic fluid seal which includes a pair of magnetic members 341, a magnet 342 between the magnetic members 341, and a magnetic fluid 343 on front surfaces of the magnetic members 341.

The magnetic sealing portion 340 may induce magnetism between a stationary magnet 342 and a rotating body. The magnetic sealing portion 340 may allow the magnetic fluid 343 to form a film (e.g., an O-ring) between a magnetic member 341 and the rotating body when the magnetic fluid 343 is injected thereinto, thus providing a sealing portion. The magnetic fluid seal may be provided as a non-contact type seal. In this case, the magnetic fluid seal may cause substantially no friction between the magnetic fluid seal and the rotating body when rotated.

In the example embodiment, the gas supply pipe 310 supplying the gas g and the rotary member 320 rotating the boat 100 may form a concentric circle in housing 330. This structure may form a twin magnetic fluid seal having a magnetic sealing portion 340 on an internal side and on an external side of the rotary member 320. A seal may therefore be implemented despite rotation of the rotary member 320.

A first bearing 351 may be between the gas supply pipe 310 and the rotary member 320. A second bearing 352 may be between the rotary member 320 and the housing 330, as well as in the magnetic sealing portion 340. The first bearing 351 and the second bearing 352 may be on opposing sides of the magnetic seal part 340 in the positions described above. The first bearing 351 and the second bearing 352 may support the rotary member 320 between the gas supply pipe 310 and the housing 330, in order to allow for rotation of the rotary member 320.

The housing 330 may be mounted in a frame unit 360 and may be fixed. The frame unit 360 may include an upper frame 361, a lower frame 362, and a connection frame 363 connecting the upper frame 361 and the lower frame 362. The housing 330 may be between the upper frame 361 and the lower frame 362 and may be connected to the connection frame 363 to be fixed to the frame unit 360 along with gas supply pipe 310. The rotary member 320 may be between the housing 330 and the gas supply pipe 310 and may be rotated using the first bearing 351 and the second bearing 352.

A seal cap 50 may be between the pedestal 200 and the base unit 300. The seal cap 50 may seal an interior of the process tube 10 to cover an open lower portion of the manifold 30. The boat 100 and the pedestal 200 may be in the process tube 10.

The upper frame 361 of the frame unit 360 may be attached to a lower surface of the seal cap 50. An O-ring 302 may be on a contact surface between the upper frame 361 and the seal cap 50. The rotary member 320 and the gas supply pipe 310 may be connected to the pedestal 200 through a central hole 51 of the seal cap 50.

The base unit 300 may not rotate the pedestal 200 and the boat 100, in a process in which the boat 100 is inserted into or extracted from the process tube 10 and in a process in which a temperature in the process tube 10 is lowered after a deposition process is completed. When the pedestal 200 is not rotated, the level of pressure of the gas g supplied through the gas supply pipe 310 may be increased to levitate the wafer W. As a result, the wafer W and the rod 130 may remain in a state of separation.

The temperature of the wafer W may be rapidly changed in the process in which the boat 100 is inserted into or extracted from the process tube 10 and in the process in which the temperature in the process tube 10 is lowered after the deposition process is completed. The wafer W may have a defect (e.g., a scratch in a location at which the wafer W is in contact with the rod 130) based on a rapid change in temperature. For example, a defect may occur based on a difference in thermal expansion coefficients between the wafer W and the boat 100. The base unit 300 may stop rotation of the rotary member 320 when temperature rapidly changes and may increase the pressure level of the gas g supplied through the gas supply pipe 310. As a result, the wafer W and the rod 130 may maintain a state of separation. A defect may therefore be prevented from occurring, or its likelihood may be reduced, in a location at which the wafer W is in contact with the rod 130.

When the pedestal 200 is rotated to perform the deposition process, the base unit 300 may reduce the level of pressure of the gas g supplied through the gas supply pipe 310, to thereby maintain the state of contact between the wafer W the rod 130.

In accordance with one or more of the aforementioned embodiments, a wafer boat assembly, and a substrate processing apparatus including a wafer boat assembly, may be provided that reduces or minimizes defects occurring at a location where a wafer contacts a boat.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise indicated. Accordingly, it will be understood by those of skill in the art that various changes in form and details may be made without departing from the spirit and scope of the present invention as set forth in the following claims.

What is claimed is:

1. A wafer boat assembly, comprising:
a boat including a slot to hold a wafer and a rod including a gas line;
a pedestal including a first surface and a connection line coupled to the gas line; and
a base, on a second surface of the pedestal, to rotate the pedestal and to supply a gas to the connection line, wherein the boat is on the first surface of the pedestal and wherein the gas is to flow along the gas line and is to be dispensed from a location at which the rod is in contact with the wafer in order to levitate the wafer.

2. The wafer boat assembly as claimed in claim 1, wherein the base includes:
a rotary structure to rotate the pedestal, the rotary structure having a cylindrical shape connected to a lower surface of the pedestal;
a gas supply pipe, in a central portion of the rotary structure, to supply the gas to the connection line;
a housing accommodating the gas supply pipe and the rotary structure; and
a magnetic seal between the gas supply pipe and the rotary structure surrounding the gas supply pipe, the magnetic seal between the rotary structure and the housing surrounding the rotary structure.

3. The wafer boat assembly as claimed in claim 2, wherein the rotary structure and the housing form a concentric circle centered on the gas supply pipe.

4. The wafer boat assembly as claimed in claim 2, further comprising:
a first bearing between the gas supply pipe and the rotary structure; and
a second bearing between the rotary structure and the housing, wherein the first bearing and the second bearing support the rotary structure between the gas supply pipe and the housing in order to allow for rotation of the rotary structure.

5. The wafer boat assembly as claimed in claim 2, further comprising:
a frame on which the housing is mounted,
wherein the rotary structure is to receive a rotational force from an external driving source and is to rotate between the housing and the gas supply pipe and wherein the housing and the gas supply pipe are fixed to the frame.

6. The wafer boat assembly as claimed in claim 4, wherein the first bearing and the second bearing are on opposing sides of the magnetic seal.

7. The wafer boat assembly as claimed in claim 5, wherein the frame includes:
an upper frame,
a lower frame, and
a connection frame,
wherein the connection frame connects the upper frame and the lower frame and wherein the housing is connected to the connection frame.

8. The wafer boat assembly as claimed in claim 2, wherein the magnetic seal is a magnetic fluid seal including a pair of magnetic portions, a magnet between the magnetic portions, and a magnetic fluid on front surfaces of the magnetic portions.

9. The wafer boat assembly as claimed in claim 1, wherein the rod includes a nozzle connected to the gas line at a location where the rod is in contact with the wafer.

10. The wafer boat assembly as claimed in claim 1, wherein the pedestal includes an opening connected to the connection line on the other surface where the pedestal faces the base.

11. The wafer boat assembly as claimed in claim 10, wherein the opening is on a same axis with respect to an axis of the base.

12. A substrate processing apparatus, comprising:
a process tube; and
a wafer boat assembly including:
a boat including a slot to hold a wafer and a rod including a gas line;
a pedestal including a first surface and a connection line coupled to the gas line; and
a base, on a second surface of the pedestal, to rotate the pedestal and to supply a gas to the connection line, wherein the boat is on the first surface of the pedestal and wherein the gas is to flow along the gas line and is to be dispensed from a location at which the rod is in contact with the wafer in order to levitate the wafer.

13. The substrate processing apparatus as claimed in claim 12, wherein:
the base includes a seal cap,
the seal cap seals an interior of the process tube with the boat, and
the pedestal in the process tube.

14. The substrate processing apparatus as claimed in claim 12, wherein:
the base is to increase a level of pressure of the gas to maintain the wafer and the rod in a state of separation when the pedestal is not rotated, and
the base is to decrease the level of the pressure of the gas to maintain a state of contact between the wafer and the rod when the pedestal is rotated.

15. The substrate processing apparatus as claimed in claim 12, further comprising a driving source connected to the base to provide a rotational force.

16. A wafer boat assembly, comprising:
a boat including rod with an internal gas line;
a pedestal with a connection line coupled to the gas line; and
a base to rotate the pedestal and supply a gas to the connection line,
wherein the gas is to be dispensed to levitate a wafer.

17. The wafer boat assembly as claimed in claim 16, wherein:
the pedestal includes an opening connected to the connection line, and
the opening is on a same axis as an axis of the base.

18. The wafer boat assembly as claimed in claim 16, wherein the base includes a gas supply pipe to supply the gas to the connection line and a magnetic seal between the gas supply pipe and the base.

19. The wafer boat assembly as claimed in claim 18, further comprising:
a first bearing; and
a second bearing,
wherein the first bearing and the second bearing are on different sides of the magnetic seal.

20. The wafer boat assembly as claimed in claim 18, wherein the magnetic seal is a magnetic fluid seal including a pair of magnetic portions, a magnet between the magnetic portions, and a magnetic fluid on front surfaces of the magnetic portions.
